(19) United States
(12) Patent Application Publication
(10) Pub. No.: US 2024/0158948 A1
(43) Pub. Date: May 16, 2024

(54) DIRECT HEATING AND TEMPERATURE CONTROL SYSTEM FOR CRYSTAL GROWTH

(71) Applicants: SLT Technologies, Inc., Los Angeles, CA (US); Kyocera Corporation, Kyoto (JP)

(72) Inventors: Paul M. VON DOLLEN, Brush Prairie, WA (US); Koji MIYAMOTO, Ikoma-gun (JP)

(21) Appl. No.: 18/388,479

(22) Filed: Nov. 9, 2023

Related U.S. Application Data
(60) Provisional application No. 63/424,794, filed on Nov. 11, 2022.

(51) Int. Cl. C30B 7/10

(52) U.S. Cl. CPC C30B 7/10

(57) ABSTRACT

Embodiments of the disclosure include a temperature control assembly for performing a crystal growth process. The temperature control assembly will include one or more temperature distribution units (TDUs) coupled to an end cap of a capsule. Each of the one or more TDUs comprise: an interior component comprising a major surface; a heating element disposed over the major surface of the interior component; a via tube comprising a central opening that is configured to accommodate lead wires, wherein the lead wires are configured to electrically connect the heating element to a power supply which is disposed on a side of the end cap that is opposite to the side on which the via tube is disposed; and a sheath layer covering the interior component, the heating element, and the via tube, wherein the sheath layer is hermetically sealed to the end cap and is configured to isolate the interior component, the heating element, and the via tube from an external environment in which the one or more TDUs are disposed during processing.

### CROSS-REFERENCE TO RELATED APPLICATIONS

This application claims priority to U.S. Provisional Application Ser. No. 63/424,794 filed Nov. 11, 2022, which is herein incorporated by reference in its entirety.

### BACKGROUND

### Field

The present disclosure generally relates to a crystal growth apparatus and method of processing the same, and more particularly, to direct heating and temperature control in a process environment during a crystal growth process.

### Description of Related Art

Current designs for autoclaves or reactors used in high temperature ammonothermal crystal growth utilize heaters distributed around the outer diameter of a process environment or process vessel. These heaters are generally used to create at least a single temperature gradient between a dissolution zone, having a lower temperature, and a growth zone, having a higher temperature, within the process environment of the process vessel. In a high temperature ammonothermal crystal growth process, nutrient, seed crystals, mineralizer, and supercritical ammonia are placed in the process environment. For example, due to retrograde solubility of gallium nitride in certain conditions, i.e., a negative coefficient with temperature, the (colder) dissolution zone, in which contains nutrient material, is typically displaced geometrically above the growth zone, in which seed crystals are placed, to drive mass transport from the nutrient zone to the growth zone through natural convection.

However, in this arrangement the hottest part of the process environment, and therefore the region of lowest solubility, are the interior walls of the process environment closest to the heaters. Thus, the driving force for crystal growth on the interior walls and parts near the interior walls of the process environment may be similar to or even exceed the driving force on the seed crystals. This creates a competition in crystal growth between the hot interior walls and the seed crystals, where deposition on the interior walls reduces the overall material efficiency of the crystal growth process and limits the possible crystal growth thickness for a given starting charge of nutrient and given growth time.

Therefore, there is a need for systems and methods that allow direct heating and temperature control within the process environment of a process vessel for high temperature ammonothermal crystal growth.

### SUMMARY

Embodiments of the disclosure include a temperature control assembly for performing a crystal growth process, comprising one or more temperature distribution units (TDUs) coupled to an end cap of a capsule. Each of the one or more TDUs comprise: an interior component comprising a major surface; a heating element disposed over the major surface of the interior component; a via tube comprising a central opening that is configured to accommodate lead wires, wherein the lead wires are configured to electrically connect the heating element to a power supply which is disposed on a side of the end cap that is opposite to the side on which the via tube is disposed; and a sheath layer covering the interior component, the heating element, and the via tube, wherein the sheath layer is hermetically sealed to the end cap and is configured to isolate the interior component, the heating element, and the via tube from an external environment in which the one or more TDUs are disposed during processing.

Embodiments of the disclosure include a temperature distribution unit (TDU) to be inserted within an internal capsule volume of a capsule of a process vessel. The temperature distribution unit (TDU) comprising: an interior component comprising a major surface; a heating element disposed over the major surface of the interior component; a via tube comprising a central opening that is configured to accommodate lead wires, wherein the lead wires are configured to electrically connect the heat element to a power supply which is disposed on a side of the end cap that is opposite to the side on which the via tube is disposed; and a sheath layer covering the interior component, the heating element, and the via tube, wherein the sheath layer is hermetically sealed to the end cap and is configured to isolate the interior component, the heating element, and the via tube from an external environment in which the one or more TDUs are disposed during processing. The temperature distribution unit (TDU) may further comprise: a first surface of a first portion of the sheath layer that is disposed over the major surface of the interior component; a second surface of a second portion of the sheath layer that is disposed over a side of the interior component that is opposite to the major surface; a plurality of openings, wherein the plurality of openings extend from the first surface to the second surface and through the interior component; and a third surface of the sheath layer which covers and defines the surfaces of each of the openings.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a direct heating and temperature control system for performing a crystal growth process according to one or more embodiments of the present disclosure.

FIG. 2 is a schematic view of a process vessel for crystal growth according to one or more embodiments of the present disclosure.

FIG. 3 is a schematic view of a direct heating and temperature control system for crystal growth according to one or more embodiments of the present disclosure.

FIG. 4A is a schematic view of a direct heating and temperature control system for crystal growth according to one or more embodiments of the present disclosure.

FIG. 4B is a schematic close-up side cross-sectional view of a portion of an interior component of a temperature distribution unit illustrated in FIG. 4A, according to one or more embodiments of the present disclosure.

FIG. 5 is a simplified partial schematic view of a direct heating and temperature control system for crystal growth according to one or more embodiments of the present disclosure.

FIG. 6A is a simplified partial schematic view of a bifacial direct heating and temperature control system for crystal growth according to one or more embodiments of the present disclosure.

FIG. 6B is a schematic close-up view of a portion of a temperature distribution unit illustrated in FIG. 6A, according to one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide direct heating and temperature control systems for growing crystals from seed crystals by use of a crystal growth process. The system includes one or more heat sources disposed within a process environment (e.g., a capsule) of a process vessel, wherein the heat sources have a surface that is near or in contact with seed crystals and/or nutrient such that the seed crystals are actively heated. One or more temperature gradients can be maintained between the seed crystals and the nutrients, independent of each other, and both the seed crystal temperature and the nutrient temperature can be controlled to be higher or lower than the temperature of the interior walls of the process environment or process vessel itself.

In the system, the seed crystals are heated such that they are the hottest surface or close to the hottest surface within the process environment, and thus interior walls of the process environment are colder than both the seed crystals and the nutrients. Thus, extremely high material deposition efficiencies can be achieved since the driving force for nucleation and crystal growth on surfaces other than the seed crystals is negligible. Furthermore, with more direct and localized control of the seed crystal temperatures as well as the nutrient temperature it is believed that both growth rates and crystal quality will be greatly improved.

In the embodiments described herein, internal heaters, referred to as “temperature distribution units” (TDUs), each having a heating element, are inserted into a process environment of a process vessel. The heating elements are electrically connected to a power supply, a controller, and other instruments disposed outside of the process vessel. Since the growth environment is generally corrosive, the internal portions of the heaters are sheathed in a corrosion-resistant material. To maintain a hermetically sealed process environment, the heaters are also sealed into a hermetically sealed boundary of the process vessel. A hermetic seal generally includes any type of reliable seal that prevents a fluid or gas from passing from one side of a seal to an opposing side of the seal. In some cases, it is desirable to perform an ASTM or ISO standard helium leak test to determine whether a sufficient hermetic seal has been created. Alternatively, each of the seed crystals can be heated by a susceptor that is heated by one or more devices which do not penetrate the processing volume of the process vessel, and can include one or more other heating methods, such as remote energy source such as lasers, or microwave generating devices, RF coils, etc., to locally control temperatures of the susceptors disposed within the process environment of the process vessel.

### Temperature Distribution Unit (TDU)

Embodiments of the disclosure include a temperature distribution unit that includes one or more heating elements that are configured to deliver energy to seed crystals and/or nutrient disposed within a processing environment of a process vessel. It is desirable for the supporting and/or connection portions of the heating elements to be cylindrical in shape to aid in forming a hermetic seal at a point where the cylindrical shaped supporting portion passes through a wall of an enclosure that surrounds the processing environment of a process vessel. However, to maintain uniform surface temperatures of the generally planar seed crystals, a temperature distribution unit (TDU) according to the embodiments described herein has a structure that distributes heat generated by the heating elements to the seed crystals. The TDU can also have seed crystals mounted directly on seed crystal supporting surfaces of the TDU or be placed in close proximity to separate seed mounting structures that are not directly mounted or attached to the TDU.

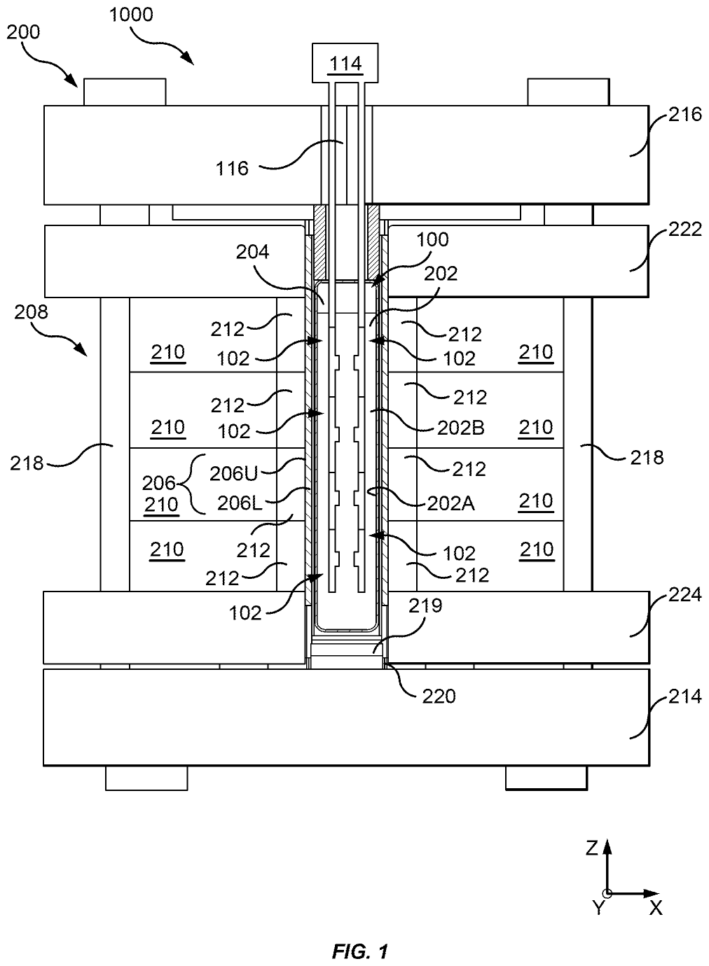

FIG. 1 is a schematic view of a system 1000 for performing a crystal growth process according to one or more embodiments of the present disclosure. The system 1000 includes a direct heating and temperature distribution unit assembly 100 and a process vessel 200 into which the temperature distribution unit assembly 100 can be inserted and sealed against to form a processing environment during a crystal formation process. The temperature distribution unit assembly 100 can include a plurality of temperature distribution units (TDUs) 102.

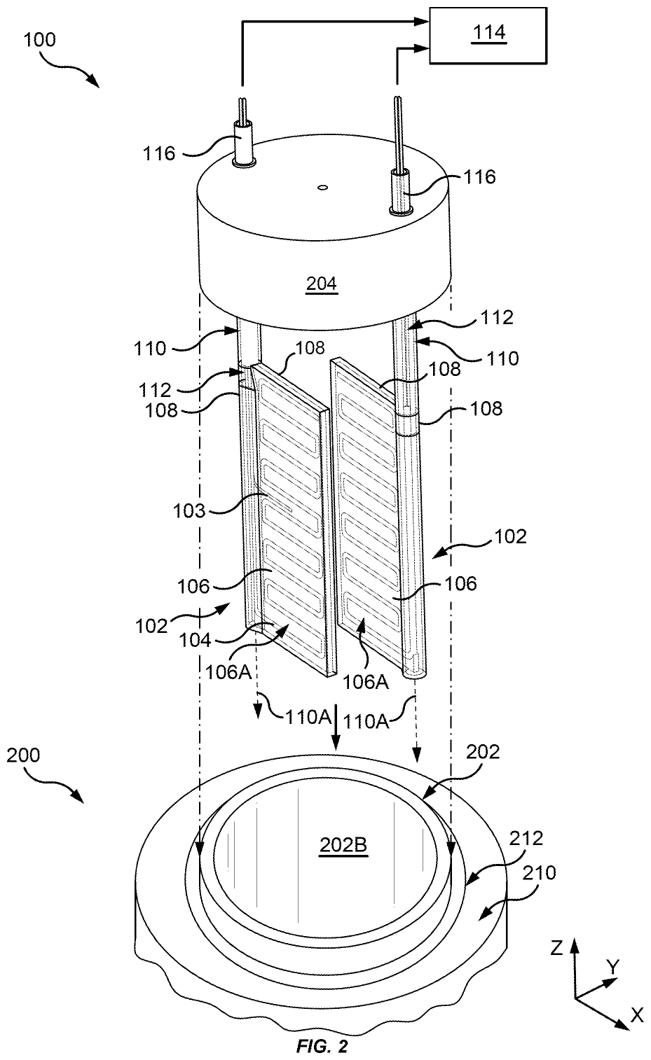

FIG. 2 depicts a temperature distribution unit assembly 100 according to one or more embodiments shown outside of a portion of the process vessel 200. As shown, in one example, the direct heating and temperature distribution unit assembly 100 includes two individual TDUs 102 that are inserted within an internal volume 202B of a capsule 202 and coupled to an end cap 204 of the capsule 202. In the embodiments shown in FIG. 2, two TDUs 102 that are parallel to each other are shown. However, in some other embodiments, the temperature distribution unit assembly 100 includes more than two TDUs 102. In some embodiments, the TDUs 102 may not be placed parallel to one another.

The TDU 102 includes a heating element 104 and an interior component 106, on which or into which the heating element 104 is mounted. The heating element 104 may be a cylindrical cartridge heater or a cable heater with or without an integrated control and/or monitoring temperature sensors, such as thermocouples 103. The heating element 104 and the interior component 106 are both covered by a sheath layer 108. The sheath layer 108 may be integrated with the interior component 106 or may be formed non-monolithically as separate assembled components from the interior component 106. The sheath layer 108 and the interior component 106 are formed of a corrosion resistant material, such as a superalloy (e.g., Hastelloy®, Udimet®, Stellite®, Inconel®, or Rene® alloys), molybdenum, or other noble metals, such as rhenium, ruthenium, rhodium, palladium, silver, osmium, iridium, platinum, gold, and alloys thereof. In the embodiments where the sheath layer 108 and the interior component 106 are non-monolithically formed as separate assembled components, the interior component 106 can be formed of corrosion-resistant and heat-resistant material with high thermal conductivity and desirable mechanical properties at high temperatures, such as molybdenum, Inconel, nickel, stainless steel, or other refractory metal, or non-metal such as graphite or carbide The sheath layer 108 may be formed of the same material as the capsule 202, or different material from the capsule 202.

The heating element 104 is mounted on or within the interior component 106. In some embodiments, the heating element 104 covered by a sheath layer is mounted on the interior component 106 that is covered by a separate sheath layer. In some other embodiments, the heating element 104 is mounted on the interior component 106 first and then the heating element 104 and the interior component 106 are covered by the common sheath layer 108, which requires less space and less sheathing material than the embodiments in which the heating element 104 and the interior component 106 require separate sheathing. Further, in the embodiments in which the heating element 104 and the interior component 106 are commonly sheathed, the heating element 104 can be bent, twisted, or otherwise routed within grooves or channels formed on a surface or within the interior component 106.

The TDU 102 further includes a via channel 110 to accommodate elements, instruments, and/or lead wires 112 to electrically connect of the heating element 104 to probes, a power supply, and a controller 114 outside of the process vessel 200 on a side of the end cap 204 that is opposite to the side on which the via channel 110 is disposed. The via channel 110 will include an external surface and an internal surface, which defines a central opening through which electrical components 112, which can include the heating elements, sensors, instruments, and/or lead wires, extend and/or pass through. The via channel 110 may be formed of a mechanically robust material, such as steel, low-carbon steel, SA723 steel, SA266 carbon steel, 4340 steel, A-286 steel, iron based superalloy, nickel based superalloy, cobalt based superalloy, Inconel 718, Rene 41, 304 stainless steel, 310 stainless steel, 316 stainless steel, 340 stainless steel, 410 stainless steel, and 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene® 88. In some embodiments, the via channel 110 is a tube that is separate from the interior component 106. In some embodiments, the via channel 110 includes one or more tubes that are mounted on or coupled to the interior component 106, or formed as an integral part of the interior component 106. The via channel 110 may have a cylindrical shape, which has an inner diameter and an outer diameter, or any other shapes or cross sections.

The outer surface of the via channel 110 is covered with the sheath layer 108. The sheath layer 108 continuously covers the heating element 104, the interior component 106, and the via channel 110, and can be hermetically sealed to a surface of the remainder of the TDU 102. The sheath layer 108 isolates the heating element 104, the interior component 106, and the via channel 110 from the process environment in which the TDU 102 is disposed during processing. The sheath layer 108 is also hermetically sealed to the end cap 204 by welding, soldering, brazing, or through mechanical seals, such, as compression fittings or O-ring seals. With the mechanical seals, the sheath layer 108 may be electrically isolated from the process vessel 200.

The heating element 104 can be in a serpentine shape, a spiral shape, or other path, to modulate total power and power density provided by the TDU 102. In some embodiments, non-heated passive elements, such as fins, plates, baffles, (not shown) formed of corrosion-resistant materials, are attached to the interior component 106 or the via channels 110, at various locations, to help control the movement of a fluid within the internal volume 202B, distribute heat or prevent heat distribution to certain areas within the internal volume 202B and/or TDU 102. These elements may modify or improve flow patterns of heat distribution within the internal volume 202B of the capsule of the process vessel 200. Examples of these elements include baffle plates spanning most or all of the internal volume 202B of the capsule 202 of the process vessel 200, or individual or smaller-scale shrouds or covers near seed surfaces to improve temperature gradients and reduce large-scale convection within the internal volume 202B of the process vessel 200. Such elements can be attached by welding directly to the hermetic sheath layer 108 or by mechanically mounting them thereon by use of wire, bolts, or clamps. These elements may also be integral with or attached to the interior component 106 and hermetically sheathed in a similar fashion as the interior component 106.

The TDU 102 may include more than one heating elements 104, which can be routed independently and/or controlled independently from the other heating elements, by the controller 114. Furthermore, the TDU 102 may accommodate one or more instruments or probes (not shown), such as thermocouples, to monitor or control the local temperature within the TDU 102.

In some embodiments, as shown in FIG. 2, the interior component 106 includes a plate having a major surface 106A that is used to control the temperature of regions within the internal volume 202B of the capsule 202. The heating element 104 is disposed over the major surface 106A of the interior component 106. In one embodiment, as shown in FIG. 2, the interior component 106 includes a vertically oriented plate that faces a direction (i.e., −y-direction) that is perpendicular to the length of the via channel 110, or said another way the major surface 106A is aligned parallel to a central axis 110A of the via channel 110, which is aligned with the length of the via channel 110 (e.g., z-direction). In some other embodiments, the interior component 106 is formed of a plate having a major surface at any angle with respect to the length of the via channel 110. For example, the interior component 106 can be a horizontal plate having a major surface 106A facing parallel to the length of the via channel 110 (e.g., perpendicular to the central axis 110A of the via channel 110), or a plate having a major surface 106A facing in a direction at an acute angle or an obtuse angle with respect to the length of the via channel 110. The outer surface of the interior component 106 can also be shaped to include helical angle type twists or tilts, which can be joined within the sheath layer 108.

The plate of the interior component 106 is formed of material with high mechanical strength at elevated temperatures, such as molybdenum, a superalloy (e.g., Inconel), or graphite. This material choice allows the TDU 102 to provide a large scale TDU 102, or a large assembly of multiple TDUs 102. For example, the via channel 110 can be threaded where the male threads of a via tube can be attached (not shown) to another TDU 102 which in turn has a via channel 110 with female threads. As long as elements, instruments, and/or lead wires 112 can be sequentially gathered, routed and connected between adjacent via channels 110, any number of TDUs 102 can be joined together. The sheath layer 108 can likewise be extended by welding of the connected via tubes after coupling the via channels 110 together.

The material used to form the interior component 106 can have a high material strength that prevents the elevated process pressures created during a crystal growth process from crushing, otherwise damaging, or distorting the heating elements 104, sensor elements, instruments, or lead wires 112 within the via channel 110. Maintaining a consistent internal geometry of the interior component 106 and the via channel 110 with high strength material also prevents the sheath layer 108 from tearing or breaking during installation or use, which may cause a leak. In some embodiments, potting or cementitious filler materials are introduced to fill small gaps in joints near the via channel 110, to provide additional mechanical support and ensure electrical isolation in key areas of the via channel 110, such as transitions between the heating element 104 and the lead wires 112. This can all be integrated in the interior component 106 prior to addition of the sheath layer 108. Cementitious filler materials may include ceramics, such as aluminum oxide, zirconium oxide, magnesium oxide, boron nitride.

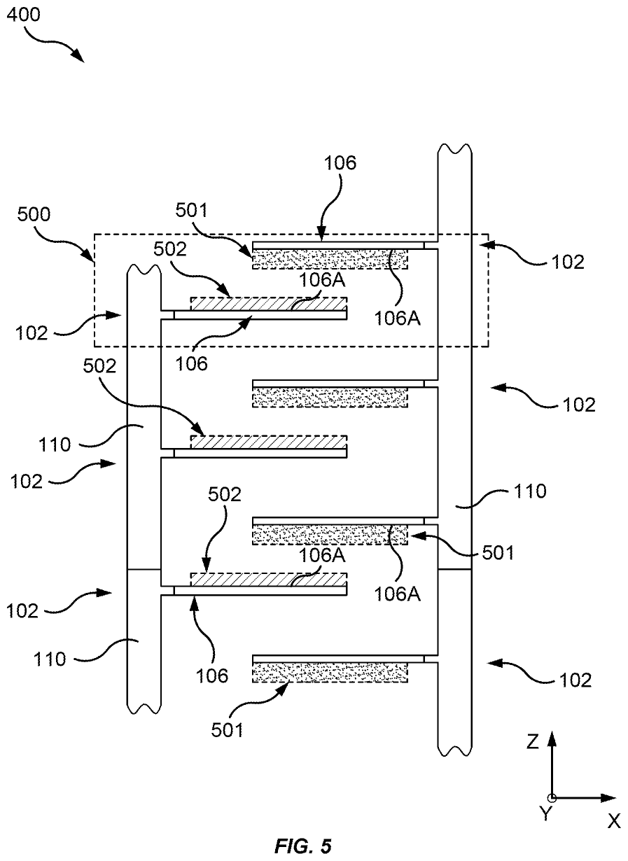

The interior component 106 can also include an insulator, such as aluminum oxide, magnesium oxide, or zirconium oxide, such that localized temperature gradients can be realized. In general, a side of the sheath layer 108 directly in contact with the heating element 104 will achieve a higher temperature than the other side of the sheath layer 108 that is directly in contact only with the interior component 106. However, in some embodiments, a difference in temperature between the side of the sheath layer 108 that includes the heating element 104 and the other side of the sheath layer 108 will be greater when an insulator is disposed on the other side of the sheath layer 108. In either case, a temperature gradient formed between the opposing sides can be used to generate a temperature gradient within the process environment of the process vessel 200. For example, nutrient material is placed in proximity to a low temperature side (i.e., lower surface side) of the sheath layer 108 of a first TDU 102 and one or more seed crystals are placed in proximity to a higher temperature side (i.e., upper surface side) of a sheath layer 108 of another adjacently positioned second TDU 102 (See FIG. 5). In some embodiments, the interior component 106 has two independently temperature controlled heating elements 104 on both sides of the interior component 106, such that one side of the interior component 106 has a higher temperature (e.g., upper side) than the other side (e.g., lower side) of the interior component 106.

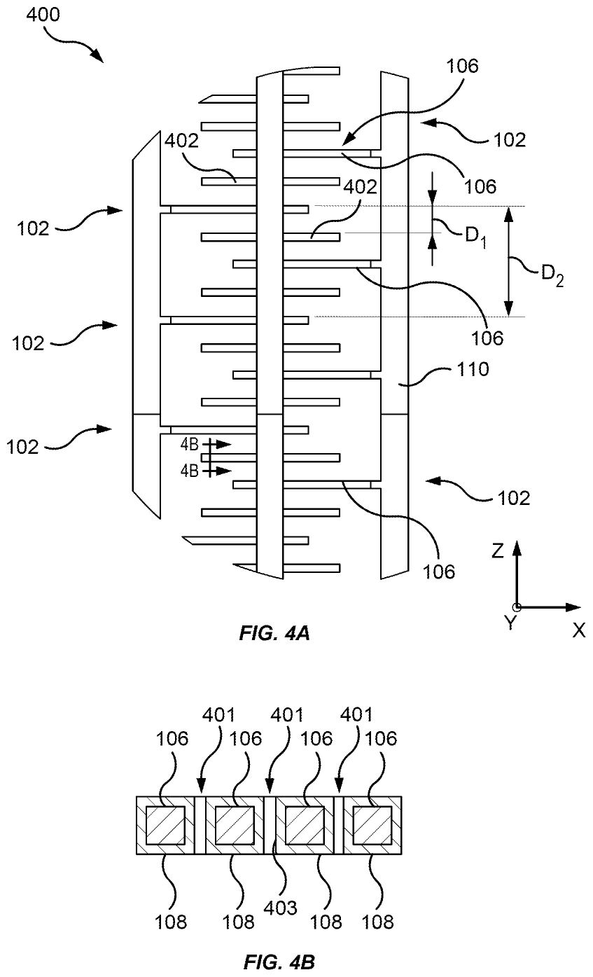

The interior component 106, heating element 104 and sheath 108 can be made with or more through holes 401 (FIG. 4B) such that fluid can pass from one side of the TDU 102 to the other side without restriction. In this case, the sheath 108 is still configured to cover the entire surface of the interior component 106, including the sidewalls 403 of the one or more holes 401. This arrangement may be advantageous where a TDU 102 is configured to service a nutrient zone (e.g., nutrient zone 501 in FIG. 5), where it is important to allow nutrient-rich fluid created during a crystal growth process to easily migrate or flow to the growth zone (e.g., growth zone 502 in FIG. 5).

In some embodiments, the TDU 102 has a load bearing portion 116 that can extend past the hermetic joint formed between the sheath layer 108 and the end cap 204. Having the load bearing portion 116 allows mechanical support of the TDU 102 from more robust structures near or around the process vessel 200. The load bearing portion 116 also improves the ability to gather and route the elements, instruments, and/or lead wires 112 since the load bearing portion 116 is an extension of the via channel 110 from within the process vessel 200, but no longer needs a hermetic sheath layer.

In some embodiments, a TDU 102 does not include a heat generating element but includes one or more temperature sensors. The temperatures sensors are provided for reference, or are used to control an external heater (e.g., the heater 206) outside of the capsule 202 or another TDU 102 having a heating element 104.

Referring to FIG. 1, the process vessel 200 includes a lower portion of the capsule 202. An internal volume 202B of the capsule 202 is a process environment of the process vessel 200 in which a high-temperature crystal growth process can be performed, such as a solvothermal crystal growth process, for example, an ammonothermal or hydrothermal process. In one configuration, within the internal volume 202B, nutrient materials and seed crystals for ammonothermal crystal growth are disposed. Typically, the nutrients are placed in a nutrient zone (also referred to as a “dissolution zone”) of the internal volume 202B and the seed crystals are placed in a growth zone, which has a higher temperature than the nutrient zone, within the internal volume 202B of the capsule 202.

In some embodiments, the end cap 204 is bonded, welded or otherwise physically joined to the capsule 202 form a hermetically sealed internal volume 202B. In other embodiments, the capsule 202 includes a Grayloc™ seal, an unsupported Bridgman seal, an O-ring seal, a c-ring seal, a confined gasket seal, a bolted closure, an AE™ closure, an EZE-Seal™, a Keuntzel closure, a ZipperClave™ closure, a threadless pin closure, or a Gasche™ gasket seal that is used to form a hermetic seal between the end cap 204 and the lower portion of the capsule 202.

In some embodiments, the capsule 202 and the end cap 204 may be formed from mechanically robust material, such as steel, low-carbon steel, SA723 steel, SA266 carbon steel, 4340 steel, A-286 steel, iron based superalloy, nickel based superalloy, cobalt based superalloy, Inconel 718, Rene 41, 304 stainless steel, 310 stainless steel, 316 stainless steel, 340 stainless steel, 410 stainless steel, and 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene® 88. In some embodiments, the capsule 202 and end cap 204 may be formed from or lined with a corrosion resistant material such as platinum, palladium, iridium, a Pt/Ir alloy, gold, or silver, titanium, rhenium, copper, iron, nickel, stainless steel, zirconium, tantalum, molybdenum, niobium, alloys thereof, and the like.

The capsule 202 is surrounded by a heater 206 that is surrounded by a stack of ring assemblies 208. During a high-temperature ammonothermal crystal growth process, the internal volume 202B of the capsule 202 is heated by the heater 206 to a temperature of between about 50° C. and 1500° C., and is filled with a process fluid, such as ammonia or water, in which a mineralizer is dissolved, under a high pressure of between about 5 MPa and about 2000 MPa. At these temperatures and pressures it is often desirable to cause the process gases to achieve a supercritical fluid state to enhance the crystal growth process. The internal volume 202B of the capsule 202 is defined by an interior surface 202A of the capsule 202.

The ring assemblies 208 each include an enclosure ring 210 and a ceramic ring 212 surrounding the enclosure ring 210. The ring assemblies 208 may provide radial confinement for pressure generated within the capsule 202 and transmitted outward through the heater 206. The heater 206 may include an upper heater 206U and a lower heater 206L that are each independently controllable.

The process vessel 200 further includes a bottom crown assembly 214, a top crown assembly 216, and tie rod fasteners 218. The bottom crown assembly 214 and the top crown assembly 216. The bottom crown assembly 214, the top crown assembly 216, and the tie rod fasteners 218 may each be formed of mechanically robust material, such as steel, low-carbon steel, SA723 steel, SA266 carbon steel, 4340 steel, A-286 steel, iron based superalloy, 304 stainless steel, 310 stainless steel, 316 stainless steel, 340 stainless steel, 410 stainless steel, 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene® 88. The end plug assembly 219 may be formed of zirconium oxide or zirconia, and mechanically supported and radially confined by end plug jackets 220. The end plug jackets 220 may be formed of steel, stainless steel, an iron-based alloy, or a nickel-based alloy. The end plug jackets 220 may also provide mechanical support and/or axial confinement for the heater 206. The process vessel 200 further includes ring supports 222, 224 that support the ring assemblies 208 on a top end and a bottom end, respectively, which are used to take some of an axial load created during processing.

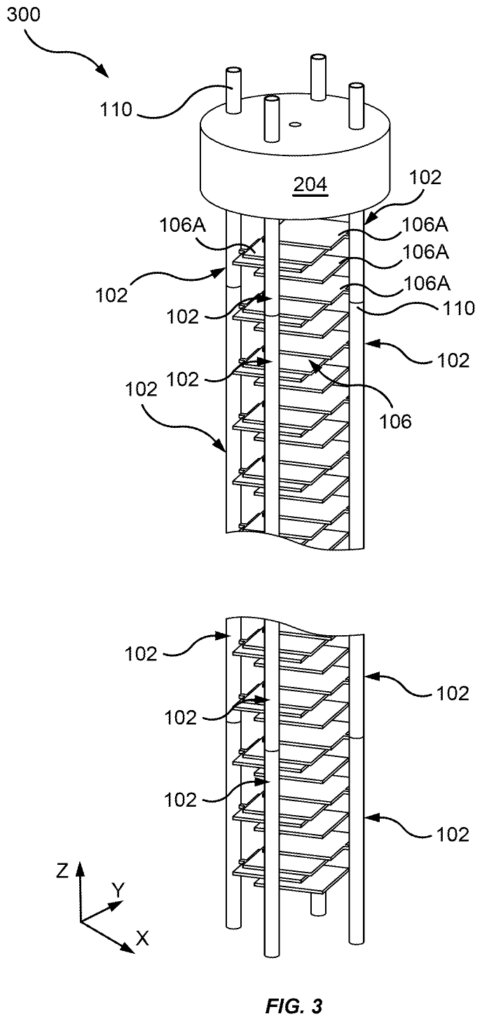

FIG. 3 is a schematic view of a direct heating and temperature control system 300 for crystal growth according to one or more embodiments of the present disclosure. In the embodiments shown in FIG. 3, the interior components 106 are oriented as horizontal plates having a major surface facing parallel to the length of the via channel 110. A heating element 104 and a sheath layer 108 are not shown in FIG. 2 for simplicity of depiction of the system. As shown, multiple TDUs 102 are assembled together sequentially along the length of the via channel 110. For example, the via channel 110 can be threaded where the threads of a first via tube mount (not shown) into another TDU 102 which in turn has a threaded via channel 110. As long as elements, instruments, and/or lead wires 112 can be sequentially gathered, routed and connected in the via channels 110, any number of TDUs 102 can be linked together. The sheath layer 108 can likewise be extended to cover the desired portions of the TDUs by orbital welding the sheath layer 108 of the butted tubes after threading the via channels 110. The extended sheath layer 108 can be hermetically sealed continuously over the assembled TDUs 102. In some other embodiments, multiple TDUs 102 are assembled together in parallel in a branching structure in which the multiple TDUs 102 connected to a single node.

This modularity of linking multiple TDUs 102 has advantages in fabricating a large-scale direct heating and temperature distribution unit assembly 100 for a deep process vessel 200 having a depth of about 2 m or more. In a deep process vessel 200, TDUs 102 can be sequentially connected while being lowered and installed into the process vessel 200 until the top TDU 102 is accessible. The elements, instruments, or lead wires 112 from the first (lowest) TDU 102 are routed through the via channel 110 in the second TDU 102 and then the first and second TDUs 102 are mechanically connected by the via channel 110. Following this a hermetic connection of the via channels 110 of the first and second TDUs 102, a continuous hermetic sheath layer 108 is formed over a connection area of the first and second TDUs 102. By repeating this procedure and using material with high strength at elevated temperatures for the interior component 106, a large-scale mechanically robust TDUs 102 can be constructed.

FIG. 4A is a schematic view of a direct heating and temperature control system 400 for crystal growth according to one or more embodiments of the present disclosure. FIG. 4B is a schematic close-up side cross-sectional view of a portion of an interior component of a temperature distribution unit created by use of a sectioning line 4B-4B shown in FIG. 4A. In the embodiments shown in FIG. 4A, the interior component 106 is formed of a horizontal plate having a major surface facing parallel to the length of the via channel 110. A heating element 104 and a sheath layer 108 are not shown in FIG. 4A. As shown, multiple TDUs 102 are assembled together sequentially along the length of each of the via channels 110, such that interior components 106 of the TDUs 102 are arranged in a staggered vertical pattern. In the example illustrated in FIG. 4, the temperature control system 400 includes four via channels 110, where one via channel 110 is hidden behind a centrally positioned via channel 110. The temperature control system 400 in this example includes interior components 106 of the TDUs 102 that are equally spaced apart by a distance D₁ and the spacing of the interior components 106 on each via channel 110 have a period or repetition distance D₂.

In some embodiments, instead of discrete hermetic joints between individual temperature distribution units 102 it could be advantageous to introduce an insulating component between the interior components 106 of two adjacent TDUs 102 to form a bifacial structure, which is discussed further below. In this configuration, an exposed surface of each of the interior components 106 is heated, such as an upper surface of an interior component 106 of a first TDU 102 and a lower surface of an interior component 106 of a second TDU 102 with an insulating component (e.g., insulating layer 602) disposed between the TDUs. This configuration could simplify the construction and application of the hermetic sheath layer 108.

The hermetic sheath layer 108 covering the assembled TDUs 102 may be formed by bending, folding, or drawing sheet metal over the already assembled interior components 106, or formed as a separate shell or form through stamping, drawing, or casting. In some embodiments, the hermetic sheath layer 108 can be added by dip-brazing, casting, or coating the assembled interior components 106 with a liquid metal layer which is then solidified. Once the hermetic sheath layer 108 is placed over the assembled interior components 106 and via channel 110 any seams or gaps can be sealed by welding, brazing, or soldering.

The elements, instruments, and/or lead wires 112 that are connected to the heating elements 104 can be routed out of the process vessel 200 through the end cap 204 that may be at a top of the process vessel 200. In some embodiments, the elements, instruments, and/or lead wires 112 are routed out of the process vessel 200 through the bottom crown assembly 214 of the process vessel 200. Routing the elements, instruments, and/or lead wires 112 through the top crown assembly 216 of the process vessel 200 has further advantages of being able to address a close-ended process vessel 200, or a process vessel 200 designed with access only from the top of the process vessel 200.

The hermetic sheath layer 108 that covers the assembled TDUs 102 may welded and hermetically sealed to the end cap 204. This welding may be performed at either inside, outside, or both inside and outside of the end cap 204. Alternatively, this welding can be done as a weld between the hermetic sheath layer 108 over the via channel 110 and a mating element (not shown) extending from the end cap 204. The mating element may be formed integral to the end cap 204, or joined to the end cap 204 in a prior operation.

The TDU 102 and the assembled TDUs 102 shown above can be efficiently used for heating one or more seed crystals mounted to or near the TDUs 102. In some embodiments, the TDU 102 or the assembled TDUs 102 are disposed such that the heater element 104 of the TDU 102 or the assembled TDUs 102 is disposed within, in contact with, or in proximity to a nutrient zone of the internal volume 202B of the capsule 202 or a growth zone of the internal volume 202B of the capsule 202.

The major surface of the interior components 106 may be placed horizontally, vertically or at an angle relative to a central axis of the via channel 110, which is aligned with the length of the via channel 110 (e.g., z-direction). For irregularly shaped nutrient zones, extra structures (not shown) to contain the nutrient zones may be added to the TDU 102.

With the use of the TDU 102 or the assembled TDUs 102 that can determine temperatures for both growth zones and nutrient zones, requirement for any other external power to the process vessel 200 or a separate external heating system (e.g., the heater 206 shown in FIG. 2) to realize adequate crystal growth process conditions may be greatly reduced.

Any number of TDUs 102 can be mounted into the process vessel 200, as long as a hermetic sheath layer 108 covers the assembled TDUs 102 and the overall size of the assembled TDUs 102 fits within the internal volume 202B defined by the inner surfaces of the capsule 202 and inner surfaces of the end cap 204. The elements, instruments, or lead wires 112 can be connected to control and monitoring systems (not shown) external to the capsule 202 in a variety of ways to create desired electrical circuits. Power supplied to the discrete circuits can be controlled individually, by the controller 114, to impose a wide variety of temperature conditions within the internal volume 202B of the capsule 202 of the process vessel 200, where portions of each TDU 102 can have a largely independently controlled temperature with respect to portions of nearby TDUs 102.

FIG. 5 is a simplified partial schematic view of the direct heating and temperature control system 400 illustrated in FIG. 4A according to one or more embodiments of the present disclosure. In some embodiments, the temperature control system 400 will include plurality of pairs of TDUs 102, which are positioned adjacently to each other and a distance apart from each other along the length of the via channel 110 (e.g., z-direction). In one example, a first pair 500 of TDUs 102 may be disposed to service a nutrient zone 501 and a growth zone 502 within the internal volume 202B of the capsule 202, to maintain a temperature gradient between the nutrient zone 501 and the growth zone 502 at a controlled value. The nutrient zone 501 can include a basket that may include a partially-enclosed structural support configured to retain nutrient material, such as a polycrystalline group III metal nitride. The growth zone 502 will include one or more seed crystals, which can, for example, include a material that includes a metal oxide, such as MXO₄ crystals, where M represents Al or Ga and X represents P or As, and metal nitrides, such as GaN, AlN, InN, InGaN, AlGaN, and AlInGaN. In some embodiments, each of the pairs of the TDUs 102 can have a similar temperature gradient formed between the adjacent nutrient zone 501 and a growth zone 502 during processing.

In another example, another pair of the TDUs 102 may be disposed to service another nutrient zone 501 and a growth zone 502 pair, other than the first pair 500, within the internal volume 202B of the capsule, but at a largely different temperature gradient from the first pair of the TDUs 102. In this case, this can be controlled due to the thermal communication within the capsule 202 being limited or controlled by use of baffling (not shown) and/or shielding (not shown) to reduce convection and radiation, respectively.

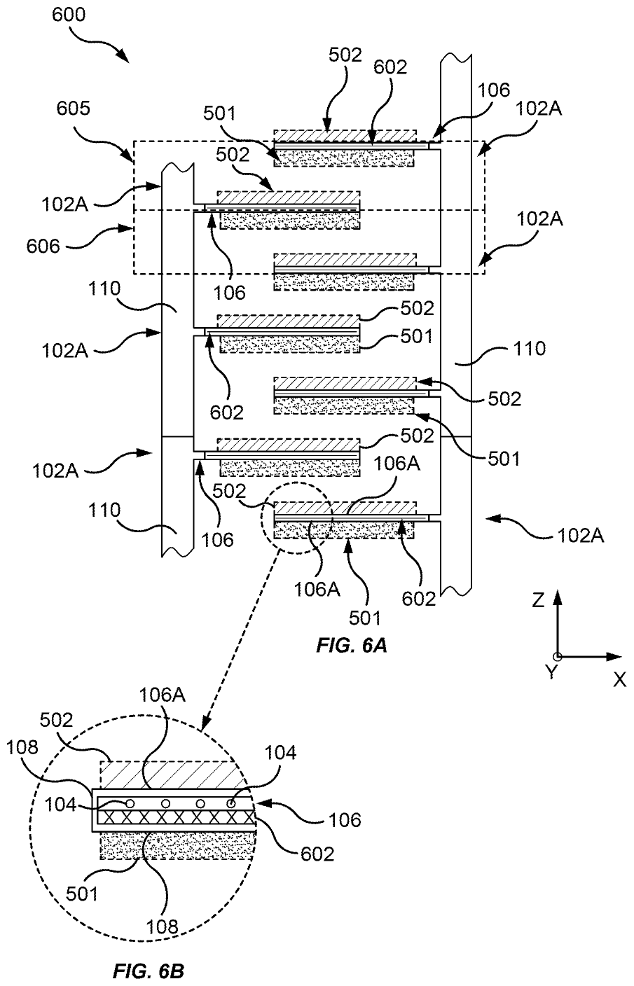

FIG. 6A is a simplified partial schematic view of a bifacial direct heating and temperature control system 600 according to one or more embodiments of the present disclosure. FIG. 6B is a schematic close-up view of a portion of an interior component 106 of a TDU 102A illustrated in FIG. 6A. Using insulating interior components 602 to make bifacial TDUs 102A increases the ability to service closely-spaced but discrete nutrient and growth zones since a single bifacial TDU 102A can service a pair of nutrient and growth zones. The insulating interior components 602 can be similarly configured as the insulating interior components 402, which is described above, and can include an insulating material such as a ceramic material, such as a metal oxide type of material. In some embodiments, the insulating interior components 602 can include alumina (Al₂O₃), magnesium oxide (MgO), zirconia (ZrO₂), silicon dioxide (SiO₂), boron nitride (BN), calcium silicate (CaSi), steatite, cordierite, or calcium magnesium oxides. In one example of the process vessel 200, a first pair 605 of the TDUs 102A may be disposed to service a nutrient zone 501 and a growth zone 502 of the first pair, and a second pair 606 of the TDUs 102A may be adjacently disposed to service a nutrient zone 501 and a growth zone 502 of a second pair within the internal volume 202B of the capsule 202.

The ability to independently impose a spectrum of temperature gradients over a large number of temperature distribution pairs within a single process vessel can also greatly enhance productivity by allowing optimization of different growth conditions in a single growth run. For example, it may be advantageous to have a certain fraction of the temperature distribution pairs (e.g., first pairs 500, First pair 605, second pair 606) operate at a relatively low temperature gradient to promote a certain mode of growth, such as favoring lateral crystal growth over vertical crystal growth, while another portion of the temperature distribution pairs operate at higher temperature gradients to promote vertical crystal growth over lateral crystal growth. In this way, in a single run, seed crystals can be grown with both high lateral crystal growth rates as well as high vertical crystal growth rates. Or, this same ability could be exploited to more rapidly and easily evaluate candidate process conditions for process development and experimentation purposes.

Mounting the TDUs 102 on the end cap 204 at the top end of the process vessel 200 also facilities easy removal post-run, especially for a deep process vessel 200, such as process vessels greater than 2 m. Similarly to a pre-run installation where TDUs 102 can be sequentially connected as being lowered and installed in the process vessel 200, TDUs 102 can be sequentially disconnected as being raised and uninstalled from the process vessel 200 for a post-run uninstallation. Following removal of the process fluid and release of high pressure, the end cap 204 can be raised along with the TDUs 102 until the first (lowest) TDU 102 of connection points is accessible. The hermetic sheath layer 108 can be cut or removed to reveal mechanical connection points on the via channels 110 or between via channels 110 and the interior components 106. The mechanical connection can be undone to release or free the TDU 102. The elements, instruments, or lead wires 112 associated with the now free TDU 102 can be handled and removed with the TDU 102, or can be cut or severed to for easier removal. The next TDU 102 can now be raised to reveal a lower connection point and the process repeated. This allows modular unloading of a deep process vessel 200 where the maximum clear height above the process vessel 200 is only a fraction of the total process vessel depth.

The embodiments described herein provide a temperature distribution unit (TDU) 102 that includes a heater element, which can be a cable heater or cartridge heater. A TDU serves to conduct heat from the heater element and distribute heat over a wider area than the heat element alone, and provides internal mechanical support to prevent distortion of the TDU at high pressures and high temperatures. A TDU can also prevent or insulate the heat flow from the heat element to certain areas of the TDU. In a bifacial TDU, one side, which can be formed of a metal (e.g., growth zone side) and having a serpentine heating element routed within a groove thereon, can be controlled to a higher uniform temperature, and the other opposing side, which can be formed of a ceramic, can have a lower temperature. In some embodiments, a heating element is routed in one side of a grooved piece of ceramic only (no metal) to achieve largely the same effect as have metal on one side and a ceramic layer on the other side. Alternatively, the major surfaces of the TDUs can be heated with no mechanical penetration (e.g., no resistive wire heating elements) into the process vessel, such as by use of other remote heating methods, such as lasers, or microwave radiation, coils, etc., to locally control temperatures within the process environment of the process vessel. A hermetic sheath can go around an entire TDU or assembled TDUs to cover internal component and via tubes, and make a hermetic joint with the process vessel to prevent leaks.

While the foregoing is directed to embodiments of the present disclosure, other and further embodiments of the disclosure may be devised without departing from the basic scope thereof, and the scope thereof is determined by the claims that follow.

1. A temperature control assembly for performing a crystal growth process, comprising:
one or more temperature distribution units (TDUs) coupled to an end cap of a capsule, each of the one or more TDUs comprising:
an interior component comprising a major surface;
a heating element disposed over the major surface of the interior component;
a via tube comprising a central opening that is configured to accommodate lead wires, wherein the lead wires are configured to electrically connect the heating element to a power supply which is disposed on a side of the end cap that is opposite to the side on which the via tube is disposed; and
a sheath layer covering the interior component, the heating element, and the via tube, wherein the sheath layer is hermetically sealed to the end cap and is configured to isolate the interior component, the heating element, and the via tube from an external environment in which the one or more TDUs are disposed during processing.

2. The temperature control assembly of claim 1, wherein the interior component comprises molybdenum, Inconel, or graphite.

3. The temperature control assembly of claim 1, wherein the interior component comprises aluminum oxide, magnesium oxide, silicon dioxide, boron nitride, calcium silicate, steatite, cordierite, calcium magnesium oxides, or zirconium oxide, to electrically isolate the heating element from an inner surface of the capsule.

4. The temperature control assembly of claim 1, wherein the via tube comprises a superalloy, zirconium, or titanium.

5. The temperature control assembly of claim 1, wherein the sheath layer comprises molybdenum, a nickel-based superalloy, or graphite.

6. The temperature control assembly of claim 1, wherein the one or more TDUs are inserted within an internal capsule volume of the capsule disposed within a process vessel, and the heating element of the one or more TDUs is disposed within, in contact with, or in proximity to a growth zone within the internal capsule volume.

7. The temperature control assembly of claim 6, wherein the heating element of the one or more TDUs is disposed within, in contact with, or in proximity to a nutrient zone within the internal capsule volume.

8. The temperature control assembly of claim 1, wherein
the one or more TDUs comprise a plurality of pairs of TDUs,
each of the plurality of pairs of TDUs comprise a first TDU and a second TDU,
the major surface of the first TDU and the major surface of the second TDU within each pair of the plurality of pairs of TDU are positioned a distance apart along a length of the via tubes of the first TDU and the second TDU; and
a temperature gradient formed between the major surface of the first TDU and the major surface of the second TDU in each of the plurality of pairs of TDUs have a constant value.

9. The temperature control assembly of claim 1, wherein the heating wherein
the one or more TDUs comprise a plurality of pairs of TDUs,
each of the plurality of pairs of TDUs comprise a first TDU to service a nutrient zone and a second TDU to service a growth zone, and
the interior component of the first TDU and the interior component of the second TDU each comprises an insulating material.

10. The temperature control assembly of claim 1, wherein the heating element comprises a cylindrical cartridge heater.

11. The temperature control assembly of claim 1, wherein the heating element comprises a cable heater.

12. The temperature control assembly of claim 1, wherein the heating element comprises a temperature sensor.

13. The temperature control assembly of claim 1, wherein the major surface of the interior component is aligned perpendicular to a length of the via tube.

14. The temperature control assembly of claim 1, wherein the major surface of the interior component is aligned parallel to a length of the via tube.

15. A temperature distribution unit (TDU) to be inserted within an internal capsule volume of a capsule of a process vessel, the TDU comprising:
an interior component comprising a major surface;
a heating element disposed over the major surface of the interior component;
a via tube comprising a central opening that is configured to accommodate lead wires, wherein the lead wires are configured to electrically connect the heat element to a power supply which is disposed on a side of the end cap that is opposite to the side on which the via tube is disposed; and
a sheath layer covering the interior component, the heating element, and the via tube, wherein the sheath layer is hermetically sealed to the end cap and is configured to isolate the interior component, the heating element, and the via tube from an external environment in which the one or more TDUs are disposed during processing.

16. The TDU of claim 15, wherein the heating element comprises a cartridge heater.

17. The TDU of claim 17, wherein the heating element comprises a temperature sensor.

18. The TDU of claim 17, wherein the interior component comprises aluminum oxide, magnesium oxide, or zirconium oxide, to electrically isolate the heating element from an inner surface of the capsule.

19. The TDU of claim 15, wherein the interior component comprises ceramic, and the heating element is routed within grooves formed on a surface of the interior component.

20. The TDU of claim 15, further comprising:
a first surface of a first portion of the sheath layer that is disposed over the major surface of the interior component;
a second surface of a second portion of the sheath layer that is disposed over a side of the interior component that is opposite to the major surface;
a plurality of openings, wherein the plurality of openings extend from the first surface to the second surface and through the interior component; and
a third surface of the sheath layer which covers and defines the surfaces of each of the openings.
